(19) United States
(12) Patent Application Publication
(10) Pub. No.: US 2026/0352978 A1
(43) Pub. Date: Nov. 5, 2026

(54) PIXEL SENSOR AND METHODS OF MAKING AND USING THE SAME

(71) Applicant: Taiwan Semiconductor Manufacturing Company Limited, Hsinchu (TW)

(72) Inventors: Yi Ching Ong, Hsinchu (TW); Wei Ting Hsieh, Hsinchu (TW); Yu-Wei Ting, Taipei City (TW); Kuo-Ching Huang, Hsinchu City (TW); Kuen-Yi Chen, Hsinchu City (TW)

(21) Appl. No.: 19/196,881

(22) Filed: May 2, 2025

(51) Int. Cl. H04N 25/772; H04N 25/771; H10F 39/00; H10F 39/18

(52) U.S. Cl. CPC H04N 25/772; H04N 25/771; H10F 39/014; H10F 39/026; H10F 39/182; H10F 39/811

(57) ABSTRACT

A pixel sensor (e.g., digital pixel sensor) may include an image sensor layer and an analog-to-digital converter (ADC) layer coupled to the image sensor layer. The ADC layer may include an ADC circuit and a memory structure coupled to the ADC circuit. The memory structure may include a data storage circuit in a back-end-of-line (BEOL) portion of the ADC layer.

### BACKGROUND

Pixel sensors (e.g., digital pixel sensors) have emerged as a key technology in the field of image capture and processing. These sensors may integrate analog-to-digital conversion at the pixel level, enabling direct digital output from each individual pixel. Such architecture offers advantages in terms of speed, noise reduction, and dynamic range compared to traditional analog pixel sensors.

Recent advancements in digital pixel sensor technology have focused on improving pixel density and reducing power consumption. Researchers have explored various circuit designs and fabrication techniques to minimize pixel size while maintaining or enhancing performance characteristics. Additionally, efforts have been made to optimize analog-to-digital converter (ADC) implementations within the pixel structure to balance conversion accuracy with area efficiency.

### BRIEF DESCRIPTION OF THE FIGURES

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic illustration of a pixel sensor (e.g., digital pixel sensor) according to one or more embodiments.

FIG. 2 illustrates a pixel circuit structure in the pixel sensor according to one or more embodiments.

FIG. 3A illustrates the memory structure according to one or more embodiments.

FIG. 3B is a schematic diagram (e.g., electrical circuit diagram) of the sub-row according to one or more embodiments.

FIG. 4 is a schematic illustration of an operation of the pixel sensor according to one or more embodiments.

FIG. 5 is a vertical cross-sectional view of the ADC layer of the pixel circuit structure according to one or more embodiments.

FIG. 6 is a top-down view of the bit-cell front-end-of-line (FEOL) layout in the FEOL portion in FIG. 5 according to one or more embodiments

FIG. 7 is a top-down view of the ADC layer according to one or more embodiments

FIG. 8 is a perspective view of the capacitor according to one or more embodiments.

FIG. 9 is a flow chart illustrating a method of making a pixel sensor according to one or more embodiments.

FIG. 10A illustrates the memory structure in an initialization stage of the imaging method according to one or more embodiments.

FIG. 10B illustrates the memory structure in a write stage of the imaging method according to one or more embodiments.

FIG. 10C illustrates the memory structure in an initialization stage of the imaging method according to one or more embodiments.

FIG. 11 is a flow chart illustrating an imaging method according to one or more embodiments.

FIG. 12 is a perspective view of the pixel sensor having an alternative configuration according to one or more embodiments.

FIG. 13 illustrates the memory structure having a first alternative configuration according to one or more embodiments.

FIG. 14A illustrates the ADC layer having a first alternative configuration according to one or more embodiments.

FIG. 14B is a top-down view of the ADC layer having the first alternative configuration according to one or more embodiments.

FIG. 15A illustrates the ADC layer having a second alternative configuration according to one or more embodiments.

FIG. 15B illustrates the local write transistor (e.g., BEOL write transistor) in the ADC layer having the second alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise. As used herein, an element or a system “configured for” a function or an operation or “configured to” provide or perform a function or an operation refers to an element or a system that is provided with hardware, and with software as applicable, to provide such a function or such an operation as described in the present disclosure, and as known in the art in the event any details of such hardware or such software are not expressly described herein.

A pixel sensor (e.g., digital pixel sensor) may be used in a CMOS image sensor to realize global shutter which may eliminate image distortion of a high-speed moving object (e.g., motion blur). A pixel sensor design may face challenges in scaling below 3 micrometers due to the limited pixel area available for integrating both analog-to-digital converters (ADCs) and sufficient in-pixel memory. A design that utilizes static random-access memory (SRAM) for data storage within the front-end-of-line (FEOL) portion of the pixel structure may struggle to accommodate the necessary 9-12 bits of memory while maintaining compact pixel dimensions. These challenges may hinder the development of high-resolution image sensors for applications requiring small form factors, such as augmented reality devices, virtual reality devices and miniature cameras. Therefore, there is an unmet need for an area-efficient pixel sensor architecture that may overcome these scaling constraints by innovatively relocating memory components, thereby enabling higher pixel densities and improved performance in advanced imaging systems.

One or more embodiments of the present disclosure may include an area-efficient pixel sensor architecture that may locate memory bits in a back-end-of-line (BEOL) portion of the pixel structure (e.g., not in the FEOL portion). The pixel sensor may, therefore, utilize BEOL metallization layers to store digital data. This novel approach may address scaling challenges in CMOS image sensors by freeing up the FEOL portion for additional circuit elements, enabling smaller pixel sizes without compromising functionality.

The pixel sensor may include an image sensor layer and an analog-to-digital converter (ADC) layer. The ADC layer may include an ADC circuit in the FEOL portion and a memory structure in the BEOL portion. The memory structure may include a data storage circuit having capacitors (e.g., ferroelectric capacitors) arranged in a crossbar array which may enable a distributed storage configuration. A 2-transistor gain cell structure may be used for efficient memory access, with local read and write transistors in the FEOL portion electrically coupled to the BEOL data storage circuit through the BEOL metallization layers.

This innovative architecture may allow for pixel sizes below 3 micrometers and support higher pixel densities in CMOS image sensors. The use of capacitors (e.g., ferroelectric capacitors) in the BEOL portion may provide non-volatile storage capabilities, while the crossbar array configuration may enable efficient data access and compact layout. The integration of memory elements in the BEOL layers may optimize (e.g., maximize) the utilization of vertical space within the pixel structure, resulting in a more area-efficient design compared to conventional approaches.

The area-efficient pixel sensor may, therefore, offer improvements in pixel density, enabling the development of higher resolution image sensors for applications such as smart glass, high-speed cameras, artificial intelligence (AI), AI glass, augmented reality (AR) devices, virtual reality (VR) headsets, surveillance cameras and surveillance systems. By overcoming the scaling challenges of related FEOL-based memory implementations, one or more embodiments, may provide for more compact and powerful imaging devices, advancing the field of digital imaging technology.

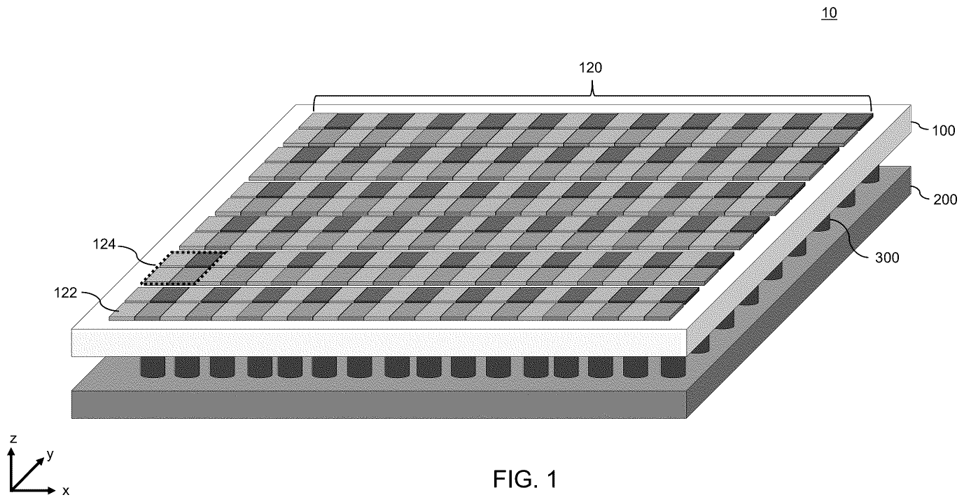

FIG. 1 is a schematic illustration of a pixel sensor 10 according to one or more embodiments. As illustrated in FIG. 1, the pixel sensor 10 may include a plurality of layers including an image sensor layer 100 and an analog-to-digital conversion (ADC) layer 200. Each of the image sensor layer 100 and the ADC layer 200 may include, for example, a semiconductor substrate (e.g., silicon substrate), active devices (e.g., transistors, diodes, etc.) on the semiconductor substrate, dielectric layers, metallization, etc.

The image sensor layer 100 may be attached to an upper surface of the ADC layer 200. In at least one embodiment, the image sensor layer 100 may be attached to the upper surface of the ADC layer 200 by a plurality of interconnect structures 300 (e.g., solder balls, bumps, etc.). The interconnect structures 300 may provide electrical coupling and facilitate a transfer of signals between the image sensor layer 100 to the ADC layer 200.

In at least one embodiment, the pixel sensor 10 may include a system-on-integrated-chip structure. In particular, the image sensor layer 100 may be included in a first semiconductor wafer. The analog-to-digital conversion (ADC) layer 200 may be included in a second semiconductor wafer. The image sensor layer 100 may be bonded to the ADC layer 200 by bonding the first semiconductor wafer to the second semiconductor wafer by wafer-to-wafer bonding.

In particular, the interconnect structures 300 may include a conductive material such as solder, copper, or gold formed into bumps that may bridge the gap between corresponding contact pads on the image sensor layer 100 and the ADC layer 200. The bumps may allow for vertical stacking of the components of the image sensor layer 100 and the ADC layer 200, providing a more compact overall design of the pixel sensor 10. The interconnect structures 300 may be formed using techniques such as controlled collapse chip connection (C4), microbumps (C2) or copper pillar bumping. The interconnect structures 300 may be arranged in an array pattern to provide robust electrical and mechanical coupling between the image sensor layer 100 and the ADC layer 200.

In at least one embodiment, the image sensor layer 100 may be attached to the upper surface of the ADC layer 200 by a direct bond (e.g., dual bond). The direct bond may include both a dielectric-dielectric bond and a metal-metal bond. In particular, a lower dielectric bonding layer (not shown) of the image sensor layer 100 may be bonded to an upper dielectric bonding layer (not shown) of the ADC layer 200. The bond between the lower dielectric bonding layer of the image sensor layer 100 and the upper dielectric bonding layer of the ADC layer 200 may constitute a dielectric-dielectric bond in the direct bond. In addition, a lower bonding pad (not shown) in the lower dielectric bonding layer of the image sensor layer 100 may be bonded to an upper bonding pad (not shown) in the upper dielectric bonding layer of the ADC layer 200. The bond between the lower bonding pad and the upper bonding pad may constitute a metal-metal bond in the direct bond.

As further illustrated in FIG. 1, the image sensor layer 100 may include a photodiode array 120 (e.g., RGB photodiode array) on an upper surface of the image sensor layer 100. The photodiode array 120 may include a structured arrangement including a plurality of rows and columns of photodiodes 122. The photodiodes 122 may be designed to detect red (R), green (G), and blue (B) light components and convert them into electrical signals for image processing. A color filter array (CFA) (such as a Bayer filter) may be placed over the photodiodes 122 to allow only specific wavelengths to reach the photodiodes 122.

The photodiode array 120 may include a plurality of pixels 124. Each of the pixels 124 may include three or more of the photodiodes 122. In at least one embodiment, each of the pixels 124 may include a 2×2 grouping of the photodiodes. The 2×2 grouping may include, for example, 2 green photodiodes, one red photodiode and one blue photodiode. Other groupings of photodiodes 122 are within the contemplated scope of disclosure. In at least one embodiment, a size of the pixels 124 in the pixel sensor 10 may be less than 3 micrometers. Other sizes of the pixels 124 are within the contemplated scope of disclosure.

Each of the photodiodes 122 may generate an analog light signal representative of the color of light sensed by the photodiode 122. The analog light signal from the photodiode 122 may be converted to a digital light signal within each pixel 124 or at the column level, reducing noise and improving readout speed. The digital light signal may be processed for color interpolation, white balance correction, and image enhancement before being output as a digital image.

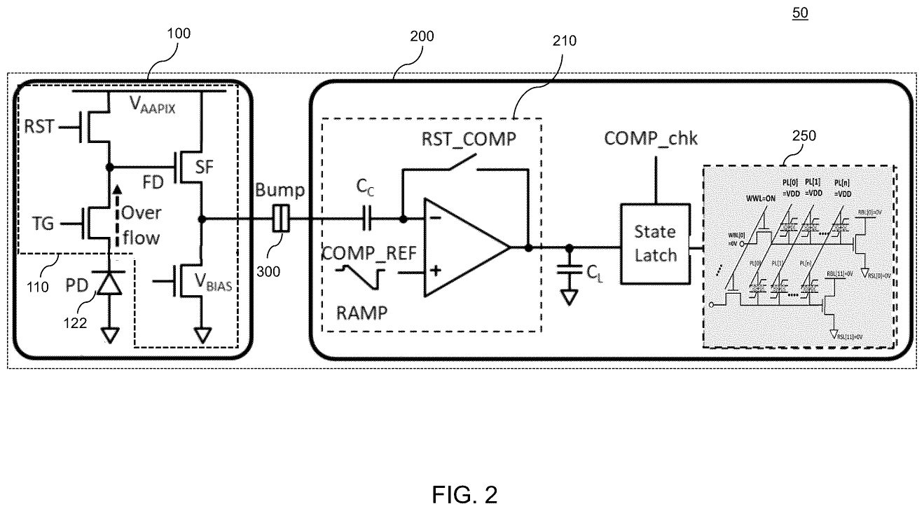

FIG. 2 illustrates a pixel circuit structure 50 in the pixel sensor 10 according to one or more embodiments. As illustrated in FIG. 2, the pixel circuit structure 50 may include an image sensing circuit 110 in the image sensor layer 100. The pixel circuit structure 50 may also include an ADC circuit 210 in the ADC layer 200. The ADC circuit 210 may be electrically coupled to the image sensing circuit 110 by one or more of the interconnect structures 300 (e.g., solder bumps).

The image sensing circuit 110 may include a complementary metal oxide semiconductor (CMOS) circuit and the image sensor layer 100 may be referred to as a CMOS image sensor layer (CIS layer). The image sensing circuit 110 may include a reset transistor (RST) coupled to one or more photodiodes 122 in the photodiode array 120. The image sensing circuit 110 may also include a transfer gate transistor (TG) coupled to the reset transistor (RST). A floating diffusion node (FD) may be located between the transfer gate transistor (TG) and the reset transistor (RST) and coupled to a gate of a source follower transistor (SF). A bias transistor (VBIAS) may be coupled between ground and the source follower transistor (SF). The ADC circuit 210 may be coupled to a node between the bias transistor (VBIAS) and the source follower transistor (SF). The voltage at the node may equal the analog voltage which represents the charge collected by the photodiode 122.

In operation, the photodiode 122 may collect light and generate a charge. The transfer gate transistor (TG) may move the collected charge from the photodiode 122 to the floating diffusion node (FD). The reset transistor (RST) may reset the floating diffusion node (FD) to a reference voltage (e.g., VDD). The source follower transistor (SF) may act as a voltage buffer, allowing the signal to be read without affecting the floating diffusion node (FD). The bias transistor (VBIAS) may ensure stable operation by setting a controlled current for the source follower transistor (SF) stage.

The ADC circuit 210 may then digitize the analog voltage from the source follower (SF) transistor (e.g., the voltage at the node between the bias transistor (VBIAS) and the source follower transistor (SF)) converting the analog voltage (e.g., analog signal) into a digital voltage (e.g., digital pixel value, raw pixel data, etc.). In particular, the ADC circuit 210 may take a snapshot of an analog voltage at one instant in time and produce a digital output code (digital voltage) which represents the analog voltage. The ADC circuit 210 may be implemented as a comparator with a ramp input (COMP_REF) and a coupling capacitor (Cc). As used herein, the term “ADC circuit” may refer to an analog-to-digital converter circuit integrated within the pixel circuit structure 50. The ADC circuit 210 may be implemented using various architectures, including but not limited to successive approximation register (SAR) ADCs, pipeline ADCs, or sigma-delta ADCs, tailored to balance power consumption, conversion speed, and area constraints of the pixel sensor 10.

The comparator-based implementation with a ramp input (COMP_REF) may allow for efficient analog-to-digital conversion through successive approximation. The coupling capacitor (Cc) may help to isolate the analog signal from the comparator, reducing noise and improving conversion accuracy. This implementation may be particularly well-suited for pixel-level integration, as it can be implemented with relatively simple circuitry while still providing adequate resolution for most imaging applications. The ramp input may allow for a controlled comparison of the input signal against a known reference, enabling precise digitization of the analog voltage from the image sensing circuit 110.

The conversion process may include the operations of charging the coupling capacitor (Cc) with the analog voltage from the image sensor circuit 110, comparing the analog voltage against a gradually increasing ramp voltage. In instances in which the ramp voltage exceeds the analog voltage, the comparator output may change state, indicating the completion of the conversion. The digital voltage (e.g., digital value) may then be determined based on the time or number of clock cycles required for the ramp to reach this threshold.

By integrating the ADC circuit 210 within each pixel 124, the pixel sensor 10 may achieve parallel conversion of a plurality of the pixels 124 simultaneously, potentially improving readout speed and reducing overall power consumption compared to analog readout architectures. This approach may also help to minimize noise introduced during signal transmission, as the analog-to-digital conversion may occur close to the signal source.

The digital voltage from the ADC circuit 210 may be input to a state latch. A capacitor (CL) may be coupled to a node between the ADC circuit 210 and the state latch. The capacitor (CL) may temporarily hold the digital voltage. The capacitor (CL) may also smooth out fluctuations in the digital voltage and reduce noise in the digital voltage. The state latch may sample and hold the digital voltage output from the ADC circuit 210. The ADC layer 200 may further include a memory structure 250 coupled to the ADC circuit 210 through the state latch. The memory structure 250 may be configured to store the digital voltage generated by the ADC circuit 210 and temporarily stored in the state latch. As shown in FIG. 2, the memory structure 250 may be include an array of memory cells (e.g., data storage circuit) and additional elements such as a row decoder, column decoder, sense amplifiers, etc. In at least one embodiment, the memory structure 250 may include a 2-transistor gain cell crossbar array.

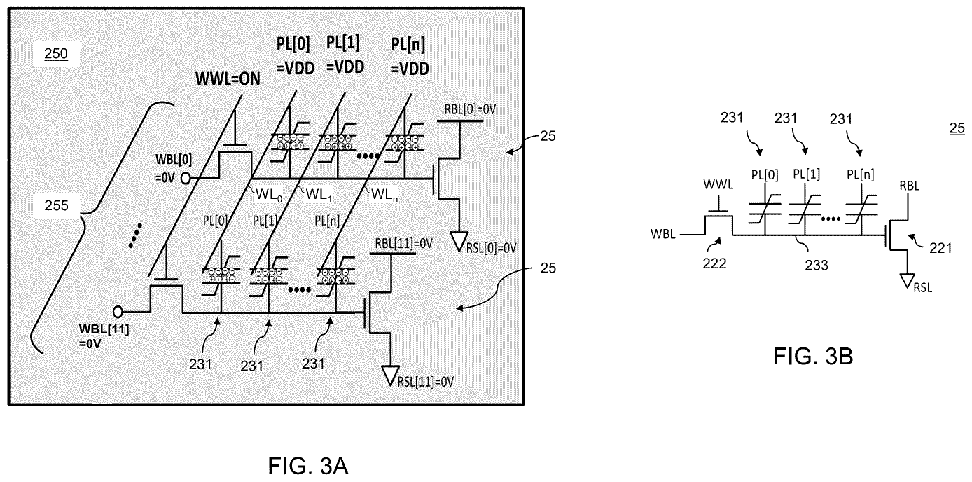

FIG. 3A illustrates the memory structure 250 according to one or more embodiments. The memory structure 250 may include a plurality of memory cells 231 that store each bit of data. The memory cells 231 may include, for example, capacitors. The memory cells 231 may also be referred to herein as capacitors 231. Other types of memory cells are within the contemplated scope of disclosure.

In at least one embodiment, the capacitors 231 may include ferroelectric capacitors. The capacitors 231 may alternatively or additionally include dielectric capacitors, metal-insulator-metal (MIM) capacitors, floating-gate capacitors, etc.

The memory structure 250 may be configured as a memory array in which the memory cells 231 are arranged in a plurality of rows and columns. A bit value of each pixel 124 may be stored in a separate memory cell 231 (e.g., one memory cell 231 per bit value). A number of the bit (0 or 1) may be used to mimic a portrait gray scale. The number of bits used to digitally encode a color of the pixel 124 in the pixel sensor 10 may depend on the bit depth and color representation of the pixel sensor 10. In at least one embodiment, the ADC circuit 210 may convert the analog signal (analog voltage) into a 12-bit digital signal (digital voltage). In that case, the 12-bit digital signal may be stored in 12 memory cells 231. Different numbers of bits (e.g., 8-bits, 14-bits, 16-bits, etc.) for the digital signal generated by the ADC circuit 210 are within the contemplated scope of disclosure.

In at least one embodiment, the memory structure 250 may include a plurality of rows 255 where each row 255 holds the pixel data for one row of the image generated by the pixel sensor 10. Thus, for example, where the image generated by the pixel sensor 10 includes one thousand (1000) rows, the memory structure 250 may include one thousand of the rows 255. A column of the memory structure 250 may correspond to a bit position of the digital signal. The capacitor 231 at a bit position for each pixel 124 may be coupled to a pixel line PL. Each pixel in the row of the image generated by the pixel sensor 10 may be associated with one pixel line PL. Thus, for example, where one row of the image includes n pixels 124 (where n may be any integer (e.g., an integer in a range from 2 to 20)), the memory structure 250 may include n pixel lines PL. A first pixel in the row of the image may be associated with pixel line PL(0), the second pixel in the row of the image may be associated with pixel line PL(1), and the nth pixel in the row of the image may be associated with pixel line PL(n).

Each row 255 of the memory structure 250 may include a plurality of sub-rows 25, one sub-row 25 for each bit position in the digital signal. Thus, for example, where the digital signal is a 12-bit digital signal, each row 255 of the memory structure 250 would be a 12-bit-wide row including 12 sub-rows 25.

FIG. 3B is a schematic diagram (e.g., electrical circuit diagram) of the sub-row 25 according to one or more embodiments. As illustrated in FIG. 3B, the sub-row 25 of the memory structure 250 may include a local read transistor 221 and a local write transistor 222. The local read transistor 221 may be coupled to the local write transistor 222 by a crossbar 233.

The crossbar 233 may be formed of a conductive material such as a metal. In particular, the crossbar 233 may include one or more layers and may include metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The sub-row 25 may also include a plurality of the capacitors 231 coupled between the pixel line PL and the crossbar 233. The number of capacitors 231 on the crossbar 233 may be equal to the number of pixel lines PL and equal to the number of pixels 124 in one row of the image. Thus, for example, where one row of the image includes n pixels 124, the sub-row 25 may include n capacitors 231.

The gain cell structure (local read transistor 221 and local write transistor 222) plus the cross bar 233 may be distributed in each of the pixels 124. Each block of the pixels 124 may be less about 0.5 kbits.

As further illustrated in FIG. 3B, the memory structure 250 may include a write bit line WBL coupled to a source of the local write transistor 222. The memory structure 250 may include a write word line WWL coupled to a gate of the local write transistor 222. The memory structure 250 may include a read source line RSL coupled to a source of the local read transistor 221. The memory structure 250 may include a read bit line RBL coupled to a drain of the local read transistor 221.

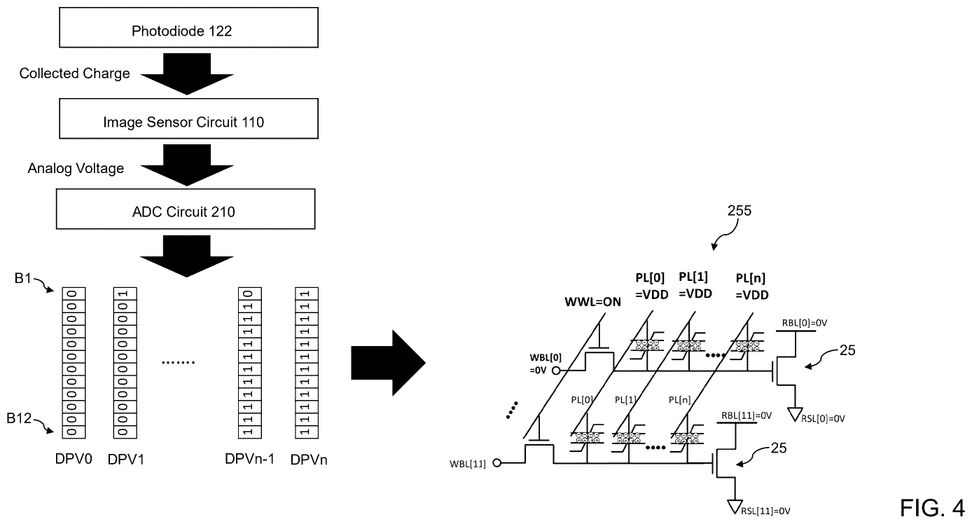

FIG. 4 is a schematic illustration of an operation of the pixel sensor 10 according to one or more embodiments. As illustrated in FIG. 4, a collected charge from a photodiode 122 in the photodiode array 120 may be transmitted to the image sensor circuit 110. The image sensor circuit 110 may generate an analog voltage (e.g., analog voltage signal) based on the collected charge. The ADC circuit 210 may convert the analog voltage to a digital pixel value (e.g., digital voltage or digital voltage signal). In particular, the ADC circuit 210 generate a digital pixel value DPV0 for a first pixel in a row of the image, a digital pixel value DPV1 for a second pixel in the row of the image, a digital pixel value DPVn−1 for an nth-1 pixel in the row of the image, and a digital pixel value DPVn for the nth pixel in the row of the image.

The digital pixel values (DPV0, DPV1, DPVn−1, DPVn) may be written (e.g., stored) into the memory structure 250. In particular, the digital pixel values may be stored in a row 255 of the memory structure 250. In instances in which, for example, the digital pixel values include 12-bit values, the first bit B1 of the digital pixel values may be written on write bit line WBL(0) in the row 255 of the memory structure 250. The twelfth bit B12 of the digital pixel values may be written on write bit line WBL (11) in the row 255 of the memory structure 250.

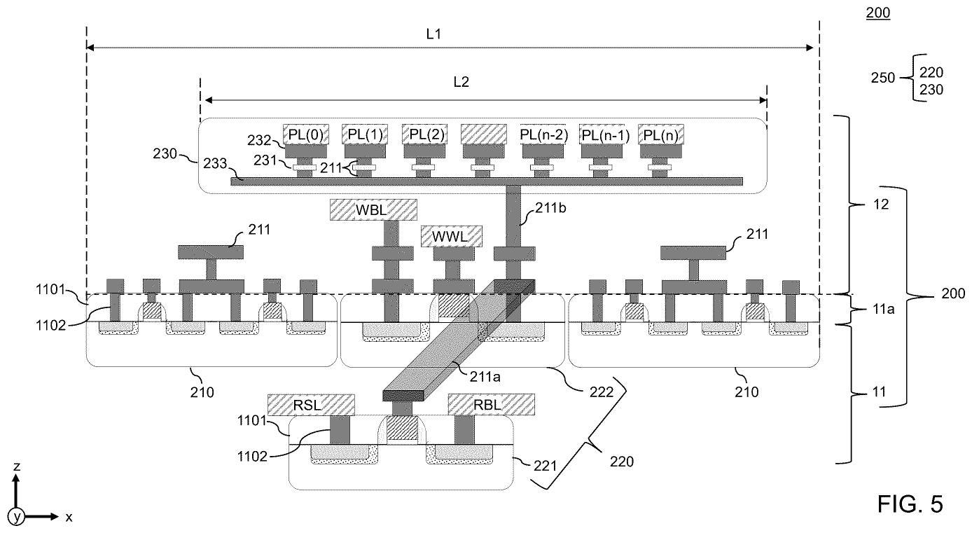

FIG. 5 is a vertical cross-sectional view of the ADC layer 200 of the pixel circuit structure 50 according to one or more embodiments. The ADC layer 200 may include a front-end-of-line (FEOL) portion 11, a middle-end-of-line (MEOL) portion 11a, and a back-end-of-line (BEOL) portion 12. The memory structure 250 may include a data access circuit 220 in the FEOL portion 11 and a data storage circuit 230 in the BEOL portion 12.

The FEOL portion 11 may include, for example, a semiconductor substrate and active devices formed on the semiconductor substrate. In particular, the FEOL portion 11 may include one or more of the ADC circuits 210 adjacent the data access circuit 220. The data access circuit 220 may include, for example, the local read transistor 221 and the local write transistor 222. As illustrated in FIG. 5, the ADC circuits 210 may be formed, for example, on opposing sides of the data access circuit 220. In at least one embodiment, the local read transistor 221 and/or the local write transistor 222 may be distributed amongst blocks of the ADC circuit 210 (ADC blocks).

The MEOL portion 11a may include an intermediate phase between the FEOL portion 11 and the BEOL portion 12. The MEOL portion 11a may include one or more dielectric layers 1101 and a plurality of contacts 1102 (e.g., gate contacts, source contacts, drain contacts, etc.) in the dielectric layers 1101. The plurality of contacts 1102 may connect the devices (e.g., transistors) in the ADC circuit 210, the local read transistor 221 and the local write transistor 222 in the FEOL portion 11 to BEOL metallization 211 in the BEOL portion 12. The dielectric layers 1101 may include, for example, silicon dioxide, fluorinated silicon dioxide (FSG), low-k dielectrics (e.g., organosilicate glass (OSG), hydrogen silsesquioxane (HSQ), etc.), polyimide-based dielectrics, etc. The plurality of contacts 1102 may include one or more layers and may include metals, metal alloys, and/or other metal-containing compounds (e.g., Cu, Al, Mo, Co, Ru, W, Ti, TiN, Ta, TaN, WN, etc.).

The BEOL portion 12 of the ADC layer 200 may include a plurality of dielectric layers (not shown). The dielectric layers may include, for example, silicon dioxide, fluorinated silicon dioxide (FSG), low-k dielectrics (e.g., organosilicate glass (OSG), hydrogen silsesquioxane (HSQ), etc.), polyimide-based dielectrics, etc. The BEOL portion 12 may also include BEOL metallization 211 in the dielectric layers. The ADC circuits 210 may share a BEOL routing footprint (e.g., a routing footprint of the BEOL metallization 211) in the BEOL portion 12.

The BEOL metallization 211 may include horizontal elements (e.g., in the x-direction and in the y-direction) and vertical elements (e.g., in the z-direction). The BEOL metallization 211 may include one or more layers and may include metals, metal alloys, and/or other metal-containing compounds (e.g., Cu, Al, Mo, Co, Ru, W, Ti, TiN, Ta, TaN, WN, etc.). In some locations, the BEOL metallization 211 may additionally or alternatively include other conductive materials such as polysilicon. Other suitable metal materials are within the contemplated scope of disclosure.

The BEOL metallization 211 may also incorporate barrier layers or liner materials such as titanium, titanium nitride, tantalum, or tantalum nitride to enhance adhesion and prevent metal diffusion. Additionally, low-k dielectric materials may be used between metal layers to reduce parasitic capacitance and improve signal propagation.

The BEOL metallization 211 may be formed through a series of deposition and patterning steps. In some embodiments, the process may begin with the deposition of a dielectric layer, followed by photolithography and etching to create trenches and vias for the metal interconnects. The metal may then be deposited using techniques such as physical vapor deposition (PVD), chemical vapor deposition (CVD), or electroplating. After metal deposition, a planarization process such as chemical-mechanical polishing (CMP) may be performed to create a flat surface for subsequent layers. This process may be repeated for multiple metal layers to create a complex interconnect structure. In coupling the crossbar 233 to the drain of the local write transistor 222, the BEOL metallization 211 may form vertical connections through vias between different metal layers. These connections may allow signals to propagate from the FEOL transistors (e.g., local read transistor 231, local write transistor 222) to the BEOL memory elements (e.g., capacitors 231). In some cases, the crossbar 233 may be formed in one of the upper metal layers, while lower metal layers may provide routing to the drain of the local write transistor 222. The specific routing and layer allocation may be optimized based on factors such as signal integrity, power distribution, and overall chip area efficiency.

Referring again to FIG. 5, the gate of the local read transistor 221 may be coupled to the drain of the local write transistor 222 by BEOL metallization 211a. The BEOL metallization 211a may be included as part of the data access circuit 220. For ease of understanding, the BEOL metallization 211a is shown as a shadow to show a possible placement of the BEOL metallization 211a. It should be noted that the BEOL metallization 211a may extend lengthwise in the y-direction between gate of the local read transistor 221 and the drain of the local write transistor 222. Put another way, the he local read transistor 221 and the drain of the local write transistor 222 may be adjacent and laterally offset from one another in the same layer (plane).

As further illustrated in FIG. 5, the local write transistor 222 may be coupled to the data storage circuit 230 of the memory structure 250 by BEOL metallization 211b. The BEOL metallization 211b may include a vertical element. In particular, the BEOL metallization 211b may extend vertically above the drain of the local write transistor 222. It should be noted that the BEOL metallization 211b is not necessarily located above the drain of the local write transistor 222. The BEOL metallization 211b may be connected to the BEOL metallization 211a at any point along BEOL metallization 211a. It should also be noted that a plurality of the BEOL metallizations 211b may be used to electrically couple the BEOL metallization 211a to the data storage circuit 230.

Further, as illustrated in FIG. 5, the data storage circuit 230 may include the crossbar 233. The crossbar 233 may be formed of the same material as the BEOL metallization 211. The crossbar 233 may extend lengthwise horizontally substantially parallel to the ADC circuits 210 in the FEOL portion 11. The crossbar 233 may also be formed, for example, within or between intermetal dielectric layers as part of the BEOL metallization 211. A plurality of the capacitors 231 may be coupled to the crossbar 233. It should be noted that while FIG. 5 shows 7 capacitors 231 coupled to the crossbar 233, any number of capacitors 231 may be coupled to the crossbar 233. In particular, the number of capacitors 231 coupled to the crossbar 233 may be equal to the number of pixels 124 in a row of the image generated by the pixel sensor 10.

The capacitors 231 may be coupled to the crossbar 233 by BEOL metallization 211. The data storage circuit 230 may also include a plurality of upper metal contacts 232 connected to the capacitors 231, respectively. The upper metal contacts 232 may be connected to the pixel lines (PL), respectively (see FIG. 3A). The upper metal contacts 232 may be coupled to the capacitors 231 by BEOL metallization 211. The upper metal contacts 232 may also be formed as part of the BEOL metallization 211.

It should be noted that the local read transistor 221/local write transistor 222 pair in the data access circuit 220 together with the crossbar 233 (with capacitors 231) in the data storage circuit 230 may constitute a sub-row 25 in the memory structure 250 (see FIG. 3A). The data access circuit 220 may include a plurality of local read transistor 221/local write transistor 222 pairs. The data storage circuit 230 may include a plurality of crossbars 233 (with capacitors 231). The number of local read transistor 221/local write transistor 222 pairs in the data access circuit 220 may be equal to the number of crossbars 233 in the data storage circuit 230.

As illustrated in FIG. 5, the ADC circuit 210 and the data access circuit 220 may have a combined length L1 in the x-direction. The data storage circuit 230 may have a length L2 in the x-direction. In at least one embodiment, the length L2 of the data storage circuit 230 may be less than or equal to the combined length L1 of the ADC circuit 210 and data access circuit 220. In at least one embodiment, the length L2 of the data storage circuit 230 may be less than 75% of the combined length L1 of the ADC circuit 210 and data access circuit 220.

The data storage circuit 230 may be located over the ADC circuit 220 and over the data access circuit 220. By locating the data storage circuit 230 over the ADC circuit 220 and the data access circuit 220 the footprint of the ADC layer 200 may be significantly reduced.

It should be noted that the ADC circuit 210 may be implemented using various architectures to suit specific application needs. In some embodiments, the ADC circuit 210 may be implemented as a successive approximation register (SAR) ADC. In other embodiments, the ADC circuit 210 may be implemented as a pipeline ADC. The choice of ADC architecture may be tailored to balance power, speed, and area constraints of the specific imaging application.

In some embodiments, the memory structure 250 may implement a column-parallel readout architecture, where each column of pixel sensors shares ADC and readout circuitry. This configuration may potentially improve readout speeds and reduce power consumption compared to a per-pixel ADC approach.

The arrangement shows the vertical integration of components within the ADC layer 200, with the data storage circuit 230 positioned above the data access circuit 220, connected through the BEOL metallization 211. This vertical integration may allow for efficient use of space within the pixel sensor 10, enabling smaller pixel sizes and higher pixel densities.

In some embodiments, additional functionality may be integrated into the BEOL layers of the ADC layer 200. For example, simple logic gates or signal conditioning circuits may be implemented in the BEOL layers to enhance pixel functionality without impacting the FEOL portion 11. This may include features such as local contrast enhancement or basic noise reduction circuits.

The structure may be oriented in a three-dimensional coordinate system as indicated by the X, Y, and Z axes shown in the lower left corner of FIG. 5. This orientation may provide a reference for understanding the spatial relationships between the various components of the memory structure 250 within the ADC layer 200.

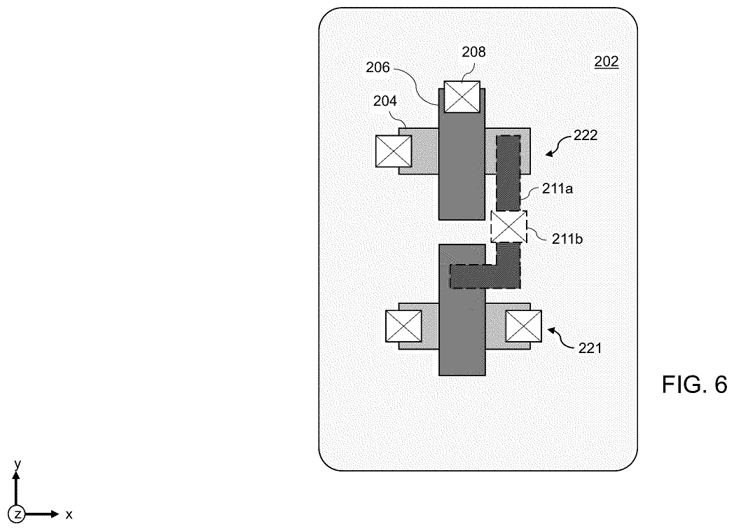

FIG. 6 is a top-down view of the bit-cell FEOL layout in the FEOL portion 11 in FIG. 5 according to one or more embodiments. The bit-cell FEOL layout may include transistors including a diffusion region 204 in the semiconductor substrate 202, a gate structure 206 over the diffusion region 204 and contact structures 208 contacting the diffusion region 204 and the gate structure 206. In particular, the bit-cell layout may include the local read transistor 221 and local write transistor 222. The gate structure 206 (gate) of the local read transistor 221 may be coupled to the drain of the local write transistor 222 by the BEOL metallization 211a which is in the BEOL portion 12. The BEOL metallization 211b may contact the BEOL metallization 211a and serve as a vertical contact structure in the BEOL portion 12. The BEOL metallization 211b may include a butted contact connected to a series of the capacitors 231.

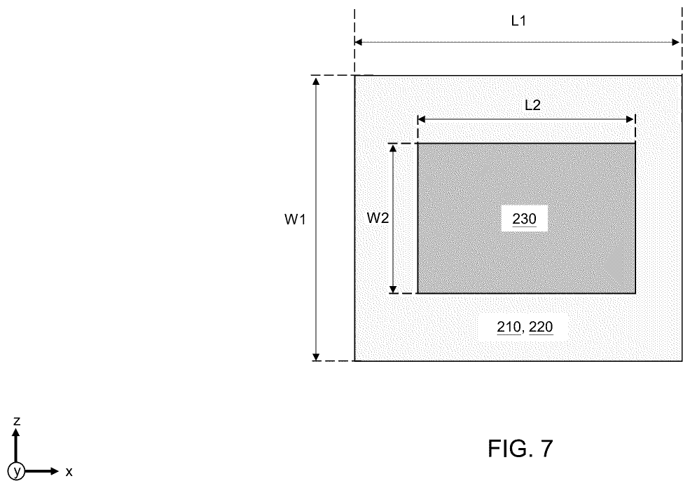

FIG. 7 is a top-down view of the ADC layer 200 according to one or more embodiments. As illustrated in FIG. 7, the ADC circuit 210 and the data access circuit 220 may have a combined width W1 in the y-direction. The data storage circuit 230 may have a width W2 in the y-direction. In at least one embodiment, the width W2 of the data storage circuit 230 may be less than or equal to the combined width W1 of the ADC circuit 210 and data access circuit 220. Thus, the area (L2×W2) of the data storage circuit 230 may be less than or equal to the combined area (L1×W1) of the ADC circuit 210 and data access circuit 220. In at least one embodiment, the area of the data storage circuit 230 may be less than 60% the combined area of the ADC circuit 210 and data access circuit 220.

With this configuration, the footprint (area) of the ADC layer 200 may be reduced by moving the data storage circuit 230 into the BEOL portion 12 of the ADC layer 200. In particular, the footprint (area) of the ADC layer 200 may be reduced at least by the area of the data storage circuit 230.

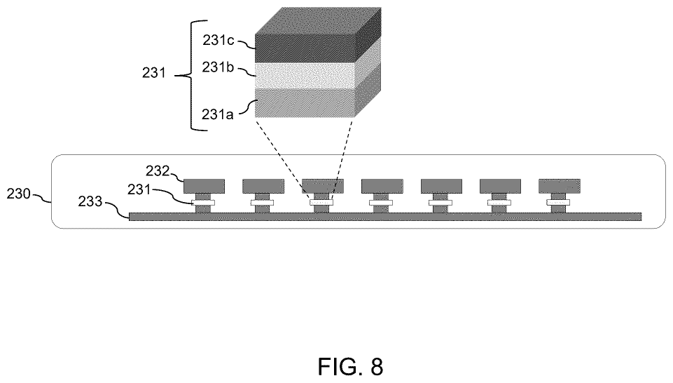

FIG. 8 is a perspective view of the capacitor 231 according to one or more embodiments. As illustrated in FIG. 8, the capacitors 231 may include metal-ferroelectric-metal (MFM) capacitors. The capacitors 231 may be referred to as ferroelectric capacitors 231. The upper portion of FIG. 8 shows an enlarged view of a capacitor 231, which may include a layered structure including a bottom electrode 231a, a ferroelectric material layer 231b, and a top electrode 231c.

The bottom electrode 231a may include, for example, one or more conductive layers. The bottom electrode 231a may include, for example, pure metal, refractory metal nitrides, conductive oxide, etc. All of the layers (e.g., metal layers) in the bottom electrode 231a may include the same or different material. In at least one embodiment, the bottom electrode 231a may one or more layers including metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

A thickness of the bottom electrode 231a may be greater than or equal to about 4 nm. Other thicknesses are within the contemplated scope of disclosure. The bottom electrode 231a may be formed, for example, by atomic layer deposition (ALD), physical vapor deposition (PVD) (e.g., sputtering, electron beam evaporation, etc.) or other suitable deposition method.

The ferroelectric material layer 231b may provide the non-volatile storage capabilities of the capacitor 231. The ferroelectric material layer 231b may include one or more layers of ferroelectric-based material. The ferroelectric material layer 231b may include, for example, a ferroelectric oxide. In particular, the ferroelectric material layer 231b may include a perovskite such as BaTiO₃, PbZrO₂, etc. The ferroelectric material layer 231b may include a fluorite-related material such as HfO₂, ZrO₂, hafnium zirconium oxide (HZO), etc. The ferroelectric material layer 231b may also include one or more wurtzite-structured nitrides such as AlScN, AlBN, GaScN, etc. Other suitable metal materials are within the contemplated scope of disclosure.

In some cases, the ferroelectric properties of the ferroelectric material layer 231b may be enhanced through post-deposition annealing processes. The annealing may be performed in different atmospheres, such as oxygen or nitrogen, and at various temperatures to optimize the crystal structure and ferroelectric characteristics. Additionally, doping of the ferroelectric material layer 231b with elements like silicon or yttrium may be implemented to further improve performance. The thickness of the ferroelectric material layer 231b may be tailored to achieve the desired capacitance and polarization properties for the specific application requirements of the pixel sensor 10.

A thickness of the ferroelectric material layer 231b may be less than or equal to about 10 nm. Other thicknesses are within the contemplated scope of disclosure. The ferroelectric material layer 231b may also be formed, for example, by atomic layer deposition (ALD), physical vapor deposition (PVD) (e.g., sputtering, electron beam evaporation, etc.) or other suitable deposition method.

The top electrode 231c may be substantially the same as the bottom electrode 231a. In particular, the top electrode 231c may include one or more conductive layers. The top electrode 231c may include, for example, pure metal, refractory metal nitrides, conductive oxide, etc. All of the layers (e.g., metal layers) may include the same or different material. In at least one embodiment, the top electrode 231c may one or more layers including metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

A thickness of the top electrode 231c may be greater than or equal to about 4 nm. Other thicknesses are within the contemplated scope of disclosure. The top electrode 231c may also be formed, for example, by atomic layer deposition (ALD), physical vapor deposition (PVD) (e.g., sputtering, electron beam evaporation, etc.) or other suitable deposition method.

The lower portion of FIG. 8 shows the data storage circuit 230 in a side view, depicting multiple capacitors 231 connected to the crossbar 233 in a distributed arrangement. The capacitors 231 may be uniformly spaced along the length of the crossbar 233, forming an integrated storage structure. This arrangement may allow for efficient data storage and retrieval within the memory structure 250 of the pixel sensor 10.

In some embodiments, the spacing between capacitors 231 along the crossbar 233 may vary depending on the specific design requirements of the pixel sensor 10. The number of capacitors 231 per crossbar 233 may also vary based on the desired storage capacity and pixel size constraints.

The integration of the capacitors 231 with the crossbar 233 in the BEOL portion 12 of the ADC layer 200 may allow for efficient utilization of vertical space within the pixel sensor 10. This vertical integration may contribute to the area-efficient design of the pixel sensor 10, potentially enabling smaller pixel sizes and higher pixel densities compared to conventional designs.

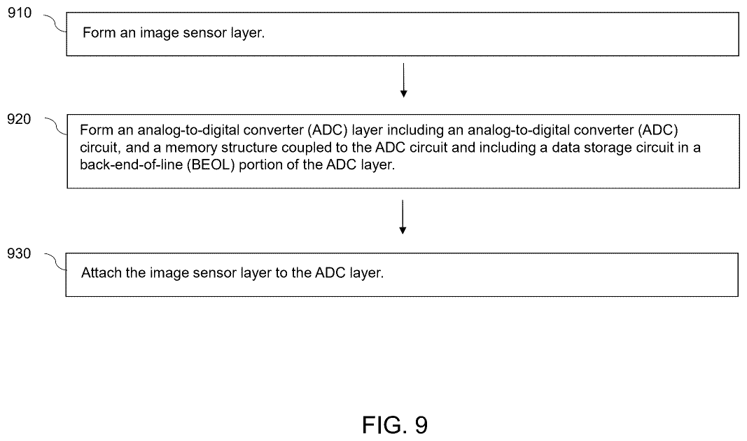

FIG. 9 is a flow chart illustrating a method of making a pixel sensor 10 according to one or more embodiments. Step 910 may include forming an image sensor layer. Step 920 may include forming an analog-to-digital converter (ADC) layer including an analog-to-digital converter (ADC) circuit, and a memory structure coupled to the ADC circuit and including a data storage circuit in a back-end-of-line (BEOL) portion of the ADC layer. Step 930 may include attaching the image sensor layer to the ADC layer.

It should be noted that the forming of the ADC layer in Step 920 may include forming the memory structure to include a data access circuit in a front-end-of-line (FEOL) portion of the ADC layer, wherein the data access circuit may include a local read transistor and a local write transistor, and a gate of the local read transistor is coupled to a drain of the local write transistor. Further, the forming of the memory structure in Step 920 may include forming the data storage circuit to include a crossbar coupling the gate of the local read transistor to the drain of the local write transistor, and a plurality of capacitors coupled to the crossbar. Further, the attaching of the image sensor layer to the ADC layer in Step 930 may include attaching the image sensor layer to the ADC layer by a plurality of bumps (e.g., solder balls, solder bumps, copper pillars, etc.) and/or by a direct bonding process.

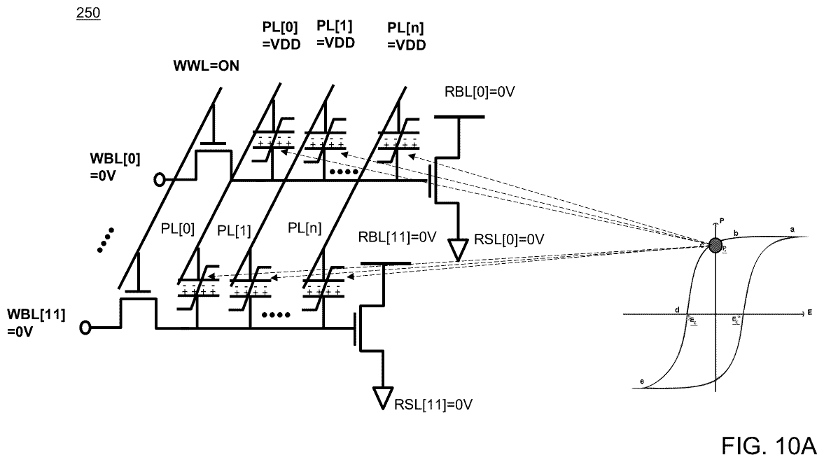

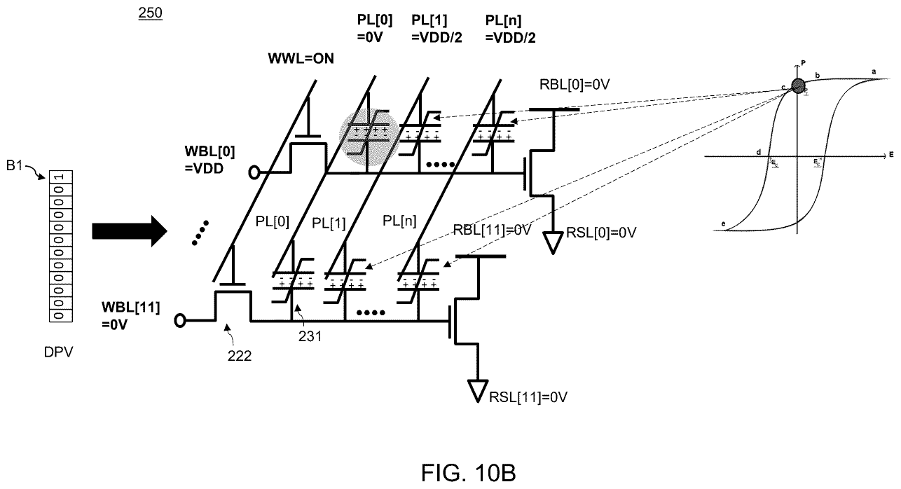

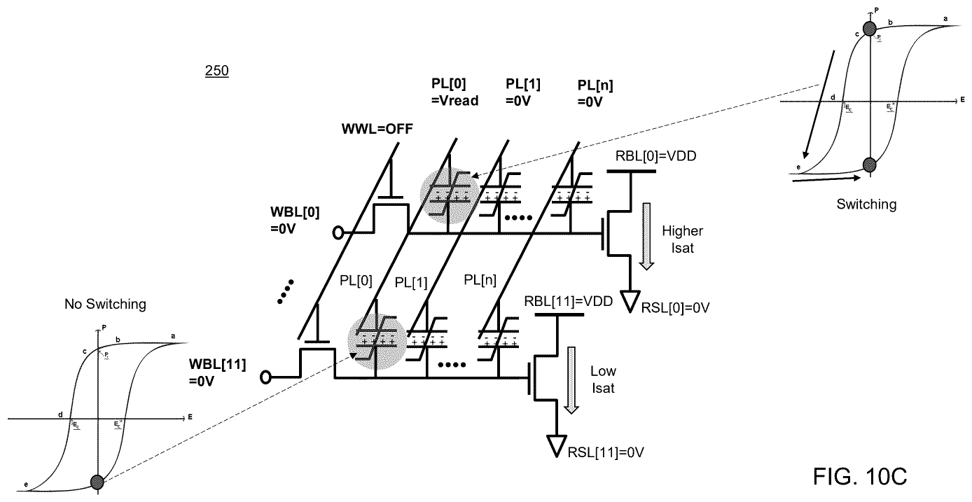

FIGS. 10A-10C illustrate the memory structure 250 during various stages of an imaging method according to one or more embodiments. FIG. 10A illustrates the memory structure 250 in an initialization stage of the imaging method according to one or more embodiments. FIG. 10B illustrates the memory structure 250 in a write stage of the imaging method according to one or more embodiments. FIG. 10C illustrates the memory structure in an initialization stage of the imaging method according to one or more embodiments.

It should be noted in FIGS. 10A-10C, the capacitor 231 may be a ferroelectric capacitor. For ease of understanding, a P-E hysteresis loop pertaining to the stage of operation may be included in each of FIGS. 10A-10C. A negative remanent polarization (−Pr) may be associated with storing a logical ‘1’. A positive remanent polarization (+Pr) may be associated with storing a logical ‘0’.

Referring to FIG. 10A, in the initialization stage, the write word line (WWL) may be turned on (e.g., activated). In addition, a voltage (VDD) may be applied to all pixel lines PL to reset all bits to positive polarization (e.g., +Pr (data “0”))

Referring to FIG. 10B, in the write stage, it is assumed that the first pixel (Pixel 1) is selected and the digital value of “00000000000001” is to be written in the first pixel. The other pixels are unselected. The pixel line PL(0) for the selected first pixel may be applied with 0V and the pixel lines PL for the unselected pixels (all other pixels) are applied with VDD/2.

In this case, the bits for the digital pixel value (DPV) may be fed through the write bit lines (WBL). In instances in which the write word line (WWL) is turned on, the DPV may be written to the bits of the selected first pixel. The write bit line WBL(0) for the first bit (B1) in the DPV may may be applied with VDD to write a −Pr (data “1”). All other write bit lines (WBL) may be applied with 0V to write a +Pr (data “0”).

In at least one embodiment, a digital signal (e.g., DPV) may be stored in the memory structure 250 by 1) activating the local write transistor 222 to write the digital signal to a ferroelectric capacitor 231, and 2) deactivating the local write transistor 222 to retain the digital signal in the ferroelectric capacitor 231.

Referring to FIG. 10C, in the read stage, it is assumed that the first pixel (Pixel 1) is selected to be read. All other pixels are unselected. Only one pixel may be read at a time. The write word line (WWL) may be turned off. The pixel line PL(1) of the selected first pixel may be applied with a read voltage Vread (e.g., VDD). The pixel lines (PL) for the other pixels are applied with 0V. All write bit lines (WBL) are applied with 0V.

In this case, the −Pr (data “1”) may be switched to +Pr (data “0”), resulting in high switching current, charging up the internal node and causing in high Isat in the local read transistor. The +Pr (data “0”) has no change in Pr, so there is no switching current and the internal node has low voltage causing a low Isat in the local read transistor.

It should be noted that the read voltage Vread may be given as follows:

$$Vread \geq Vc \times \frac{{C}_{MOS} + {nC}_{MFM}}{{C}_{MOS} + n - 1 {C}_{MFM}}$$

where Vc is a coercive voltage, C_{MOS} is MOS capacitance, C_{MFM} is MFM capacitance, and n is the number of pixels in parallel.

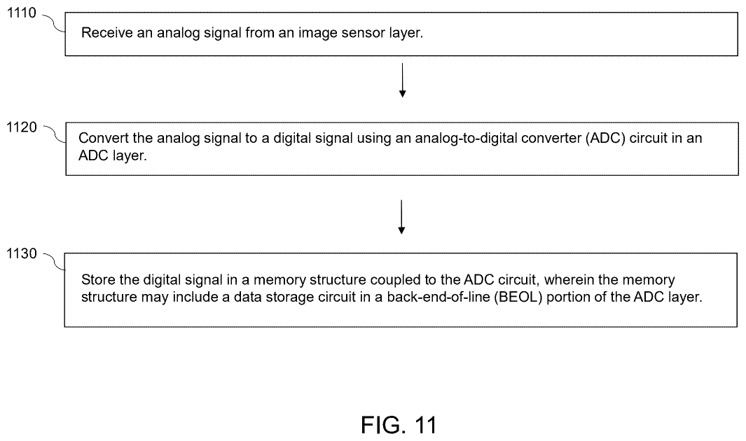

FIG. 11 is a flow chart illustrating an imaging method according to one or more embodiments. Step 1110 may include receiving an analog signal from an image sensor layer. Step 1120 may include converting the analog signal to a digital signal using an analog-to-digital converter (ADC) circuit in an ADC layer. Step 1130 may include storing the digital signal in a memory structure coupled to the ADC circuit, wherein the memory structure may include a data storage circuit in a back-end-of-line (BEOL) portion of the ADC layer. The memory structure may also include a data access circuit in a front-end-of-line (FEOL) portion of the ADC layer, and the storing of the digital signal may include accessing the memory structure using a local read transistor or a local write transistor of the data access circuit. The data storage circuit may include a crossbar coupling the gate of the local read transistor to the drain of the local write transistor, and the storing of the digital signal may include storing the digital signal in a plurality of capacitors coupled to the crossbar. Further, the capacitors may include ferroelectric capacitors and the storing of the digital signals in the ferroelectric capacitors may include changing the polarization of the ferroelectric capacitors.

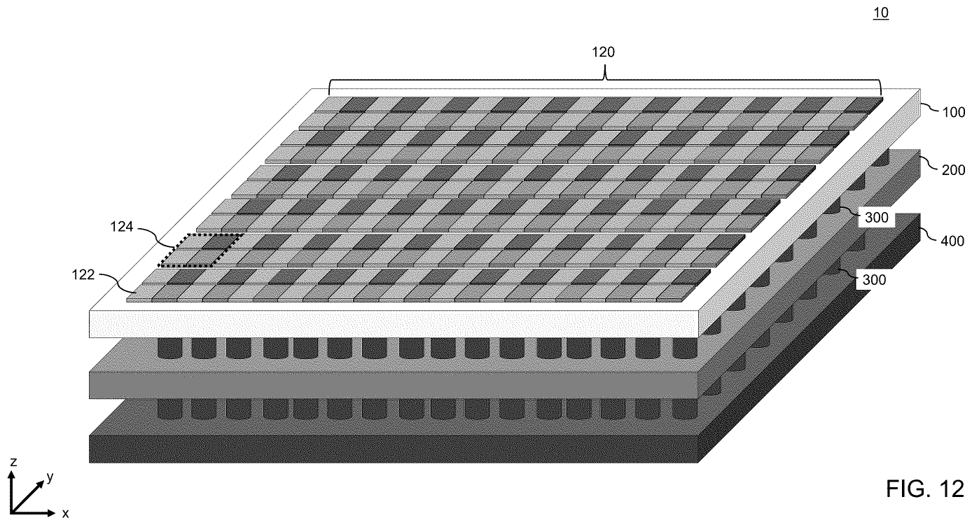

FIG. 12 is a perspective view of the pixel sensor 10 having an alternative configuration according to one or more embodiments. As illustrated in FIG. 12, the pixel sensor 10 having the first alternative configuration may be substantially similar to the pixel sensor 10 in FIG. 1. In particular, the pixel sensor 10 having the first alternative configuration may include the image sensor layer 100 in a first semiconductor wafer and the ADC layer 200 in a second semiconductor wafer. The image sensor layer 100 may also be bonded to the ADC layer 200 by the interconnect structures 300 and/or by direct bonding (e.g., a combination of metal-metal bonding and dielectric-dielectric bonding). Further, the image sensor layer 100 may be bonded to the ADC layer 200 by bonding the first semiconductor wafer to the second semiconductor wafer by wafer-to-wafer bonding.

However, the pixel sensor 10 having the first alternative configuration may also include a computing layer 400 in a third semiconductor wafer. The computing layer 400 may include a computing circuit of the pixel sensor 10. The computing circuit may include, for example, an image signal processing circuit performing image enhancement and correction and a control logic and timing generating circuit. The computing circuit may also an AI and machine learning circuit for real-time enhancement.

The ADC layer 200 may be bonded to the computing layer 400 by the interconnect structures 300 and/or by direct bonding (e.g., a combination of metal-metal bonding and dielectric-dielectric bonding). Further, ADC layer 200 may be bonded to the computing layer 400 by bonding the second semiconductor wafer to the third semiconductor wafer by wafer-to-wafer bonding.

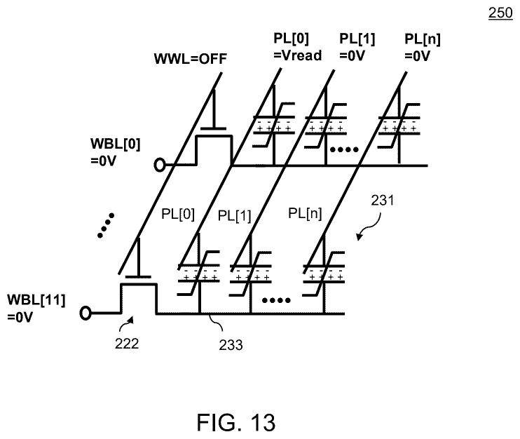

FIG. 13 illustrates the memory structure 250 having a first alternative configuration according to one or more embodiments. As illustrated in FIG. 13, the memory structure 250 having the first alternative configuration may be substantially similar to the memory structure 250 in FIG. 3A. In particular, the memory structure 250 may include the local write transistor 222 coupled to the crossbar 233, and the plurality of capacitors 231 (e.g., memory cells) coupled to the crossbar 233.

However, in contrast to the memory structure 250 in FIG. 3A, the memory structure 250 having the first alternative configuration may not include the local read transistors 221. Thus, unlike the memory structure 250 in FIG. 3A which may have a gain cell+crossbar structure, the memory structure 250 in FIG. 13 may have at 1-transistor+crossbar structure.

The memory structure 250 having the first alternative configuration may perform a read operation using charge sensing techniques that do not require the use of the local read transistor 221. Such charge sensing techniques may include, for example, applying a read voltage to a capacitor and detecting a voltage shift using a differential sense amplifier, applying a read voltage to a wordline and detecting a difference in current levels with a current sense amplifier, etc. The first alternative configuration may, therefore, allow the ADC layer 200 to have a smaller footprint compared to the ADC layer 200 where the memory structure 250 includes the local read transistors 221.

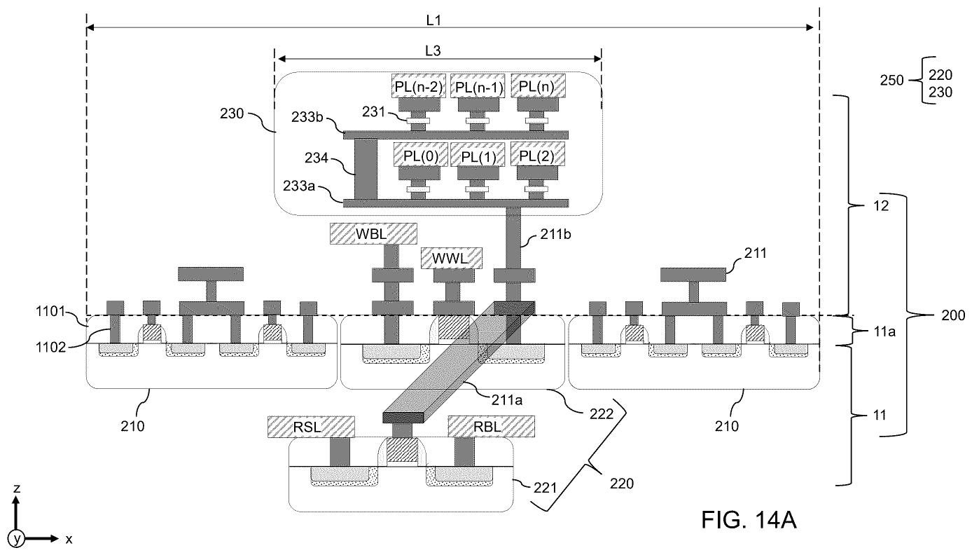

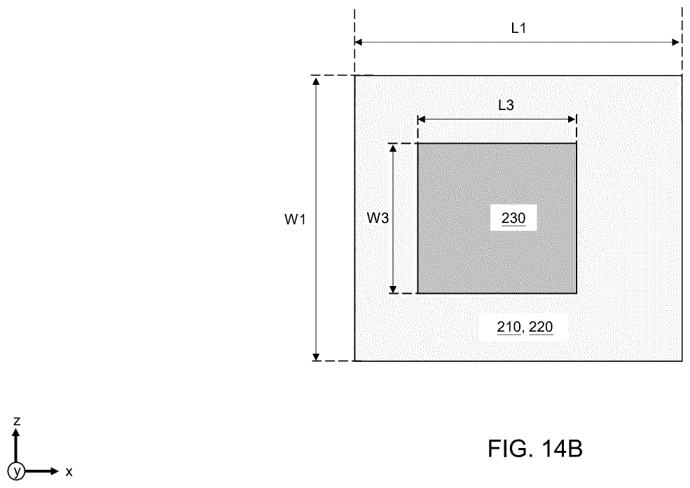

FIG. 14A illustrates the ADC layer 200 having a first alternative configuration according to one or more embodiments. As illustrated in FIG. 14A, the ADC layer 200 having the first alternative configuration may be substantially similar to the ADC layer 200 in FIG. 5. In particular, the ADC layer 200 having the first alternative configuration may include the FEOL portion 11 including the ADC circuit 210 and the data access circuit 220. The ADC layer 200 having the first alternative configuration may also include the MEOL portion 11a and the BEOL portion 12 including the data storage circuit 230.

However, in contrast to the ADC layer 200 in FIG. 5 where the data storage circuit 230 may include capacitors 231 in the same layer (e.g., 2TnC with same-layer raw cap), the ADC layer 200 having the data storage circuit 230 in the first alternative configuration may include capacitors 231 having a stacked configuration (e.g., 2TnC with stacked raw cap). In particular, as illustrated in FIG. 14A, the data storage circuit 230 may include a stacked structure including 2 or more layers of crossbars 233 (e.g., a crossbar stack including two or more crossbars 233). The crossbar 233 may include a lower crossbar 233a coupled to the drain of the local write transistor 222. The data storage circuit 230 may also include an upper crossbar 233b coupled to the lower crossbar by a connecting structure 234. The plurality of capacitors 231 may coupled to the lower crossbar 233a and the upper crossbar 233b.

As with the data storage circuit 230 in FIG. 5, the data storage circuit 230 in FIG. 14A may be formed in the dielectric layers (e.g., interlayer dielectric layers) of the BEOL portion 12. Each of the lower crossbar 233a and the upper crossbar 233b may include, for example, the BEOL metallization 211 in the dielectric layers of the BEOL portion 12. The connecting structure 234 may also include a vertical element (e.g., via structure) of the BEOL metallization 211 in the dielectric layers of the BEOL portion 12.

As illustrated in FIG. 14A, the ADC circuit 210 and the data access circuit 220 may have the combined length L1 in the x-direction. The data storage circuit 230 may have a length L3 in the x-direction. In at least one embodiment, the length L3 of the data storage circuit 230 may be less than or equal to the combined length L1 of the ADC circuit 210 and data access circuit 220. In at least one embodiment, the length L3 of the data storage circuit 230 may be less than 50% of the combined length L1 of the ADC circuit 210 and data access circuit 220.

The data storage circuit 230 may be located over the ADC circuit 220 and over the data access circuit 220. The data storage circuit 230 may be located primarily over the data access circuit 220. In at least one embodiment, the length L3 of the data storage circuit 230 may be no more than 1.5 times a length of the local write transistor 222 in the x-direction. By forming the data storage circuit 230 to have a stacked structure, the ADC layer 200 having first alternative configuration may be able to maintain a small footprint of the ADC layer 200 even in a case where the data storage structure 230 includes many capacitors 231 (e.g., more than 10 capacitors 231) on the crossbar 233.

FIG. 14B is a top-down view of the ADC layer 200 having the first alternative configuration according to one or more embodiments. Similar to the ADC layer 200 in FIG. 7, in the ADC layer 200 having the first alternative configuration in FIG. 14B the ADC circuit 210 and the data access circuit 220 may have a combined width W1 in the y-direction. The data storage circuit 230 may have a width W3 in the y-direction. The width W3 of the data storage circuit 230 may be less than or equal to the combined width W1 of the ADC circuit 210 and data access circuit 220. Thus, in ADC layer 200 having the first alternative embodiment, the area (L3×W3) of the data storage circuit 230 may be less than or equal to the combined area (L1×W1) of the ADC circuit 210 and data access circuit 220. In at least one embodiment, the area of the data storage circuit 230 may be less than 30% the combined area of the ADC circuit 210 and data access circuit 220. This configuration may allow other elements of the ADC layer 200 (e.g., elements of the ADC circuit 210) to be moved into the BEOL portion 12, further reducing the footprint (area) of the ADC layer 200.

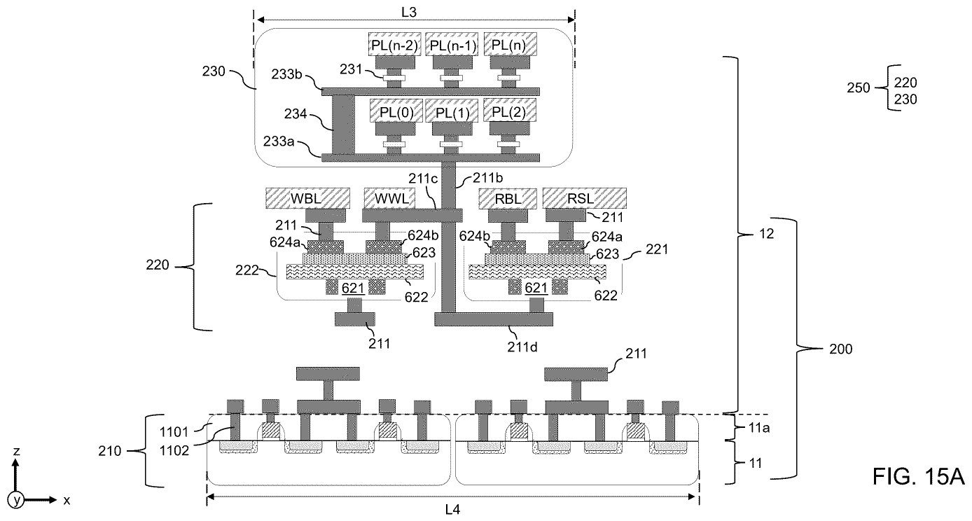

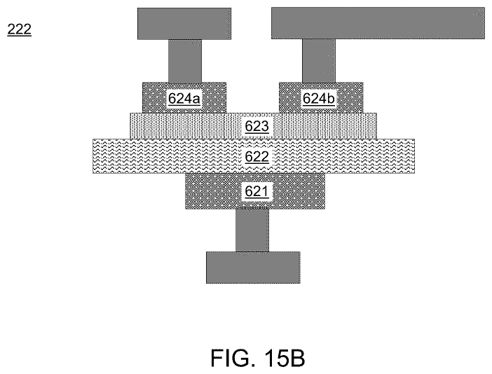

FIG. 15A illustrates the ADC layer 200 having a second alternative configuration according to one or more embodiments. As illustrated in FIG. 15A, the ADC layer 200 having the second alternative configuration may be substantially similar to the ADC layer 200 having the first alternative configuration in FIG. 14A. In particular, the ADC layer 200 having the second alternative configuration may include the FEOL portion 11 including the ADC circuit 210, the MEOL portion 11a and the BEOL portion 12 including the data storage circuit 230. The data storage circuit 230 of the ADC layer 200 having the second alternative configuration may have a stacked configuration including a lower crossbar 233a and an upper crossbar 233b and capacitors 231 coupled to the lower crossbar 233a and the upper crossbar 233b.

However, in contrast to the first alternative configuration in FIG. 14A, the second alternative configuration of the ADC layer 200 may have the data access circuit 220 in the BEOL portion 12. Thus, the data access circuit 220 may be removed from the FEOL portion 11 further reducing the footprint of the ADC layer 200. In particular, the footprint of the ADC layer 200 may be limited to the footprint of the ADC circuits 210. Further, the ADC circuits 210 may have a length L4 in the x-direction which may be no more than 1.5 times the length L3 of the data storage circuit 230 in the x-direction.

The data access circuit 220 may be located in the BEOL portion 12 over the ADC circuits 210. The data storage circuit 230 may be located over the data access circuit 220. The data storage circuit 230 may be located between the data storage circuit 230 and the ADC circuits 210.

In this configuration, the local read transistor 221 may be referred to as a BEOL read transistor 221 and the local write transistor 222 may be referred to as a BEOL write transistor 222. The local read transistor 221 and the local write transistor 222 may have a similar configuration. In particular, each of the local read transistor 221 and the local write transistor 222 may include a gate 621 (e.g., metal gate), a gate insulating layer 622, a semiconductor layer 623 that may include a source and drain regions and a channel region between the source and drain regions, and a source contact 624a (metal contact) contacting a source region in the semiconductor layer 623, and a drain contact 624b (metal contact) contacting a drain region in the semiconductor layer 623. The source contact 624a and drain contact 624b may be formed on opposite sides of the semiconductor layer 623.

The local read transistor 221 and the local write transistor 222 may be formed in the dielectric layers (e.g., interlayer dielectric layers) of the BEOL portion 12. Each of the local read transistor 221 and the local write transistor 222 may be coupled to the data storage circuit 230, for example, the BEOL metallization 211 in the dielectric layers of the BEOL portion 12. In particular, the drain contact 624b of the local write transistor 222 may be coupled to the BEOL metallization 211b by BEOL metallization 211c. The gate 621 of the of the local read transistor 221 may be coupled to the BEOL metallization 211b by BEOL metallization 211d

As further illustrated in FIG. 15A, the write bit line (WBL) may be coupled to the source contact 624a of the local write transistor 222. The write word line (WWL) may be coupled to the drain contact 624b of the local write transistor 222. The read bit line (RBL) may be coupled to the drain contact 624b of the local read transistor 221. The read source line (RSL) may be coupled to the drain contact 624b of the local read transistor 221.

FIG. 15B illustrates the local write transistor 222 (e.g., BEOL write transistor) in the ADC layer 200 having the second alternative configuration according to one or more embodiments. It should be noted that the local read transistor 221 (e.g., BEOL read transistor) may have a substantially similar configuration as the local write transistor 222.

The gate 621 may include, for example, one or more conductive layers. In particular, the gate 621 may include a conductive electrode including pure metal, refractory metal nitrides, conductive oxide, etc. The conductive layers may include metal layers that include the same or different material. The gate 621 may have a thickness greater than or equal to about 10 nm. Other materials and thicknesses for the gate are within the contemplated scope of disclosure.

The gate insulating layer 622 may include an insulating material such as an oxide, nitride or oxynitride. In particular, the insulating layer 622 may include a perovskite oxide, nitride or oxynitride (e.g., ZrO₂, HfO₂, TiO₂, BaTiO₃, SrTiO₃, HfON, ZrON, etc.). The gate insulating layer 622 may have a thickness greater than or equal to about 1.5 nm. Other materials and thicknesses for the gate insulating layer 622 are within the contemplated scope of disclosure.

The semiconductor layer 623 may include a semiconducting material such as a semiconducting oxide. In particular, the semiconductor layer 623 may include AlScN, IGZO, ZnO, etc. The semiconductor layer 623 may also include a group III-V semiconducting material such as GaN, or a group IV semiconducting material such as silicon, SiGe, Ge, et. The semiconductor layer 623 may have a thickness greater than or equal to about 20 nm. Other materials and thicknesses for the semiconductor layer 623 are within the contemplated scope of disclosure.

The source contact 624a and drain contact 624b may be formed of materials substantially similar to the materials in the gate 621. In particular, the source contact 624a and drain contact 624b may include, for example, one or more conductive layers. In particular, the source contact 624a and drain contact 624b may include a conductive electrode including pure metal, refractory metal nitrides, conductive oxide, etc. The conductive layers may include metal layers that include the same or different material. The source contact 624a and drain contact 624b may have a thickness greater than or equal to about 4 nm. Other materials and thicknesses for the source contact 624a and drain contact 624b are within the contemplated scope of disclosure.

Referring to FIGS. 1-15B, a pixel sensor 10 may include an image sensor layer 100, and an analog-to-digital converter (ADC) layer 200 coupled to the image sensor layer 100 including an analog-to-digital converter (ADC) circuit 210, and a memory structure 250 coupled to the ADC circuit 210 including a data storage circuit 230 in a back-end-of-line (BEOL) portion 12 of the ADC layer 200.

In one embodiment, the memory structure 250 may further include a data access circuit 220 in a front-end-of-line (FEOL) portion 11 of the ADC layer 200. In one embodiment, the data access circuit 220 may include a local read transistor 221 and a local write transistor 222, and a gate of the local read transistor 221 may be coupled to a drain of the local write transistor 222. In one embodiment, the data storage circuit 230 may include a crossbar 233 coupled to the gate of the local read transistor 221 and to the drain of the local write transistor 222, and a plurality of capacitors 231 coupled to the crossbar 233. In one embodiment, the plurality of capacitors 231 may include a plurality of ferroelectric capacitors 231. In an embodiment, each of the ferroelectric capacitor 231 of the plurality of ferroelectric capacitors 231 may include a bottom electrode 231a, a ferroelectric material layer 231b on the bottom electrode 231a, and a top electrode 231c on the ferroelectric material layer 231b. In one embodiment, the ADC layer 200 may further include BEOL metallization 211 in the BEOL portion 12 of the ADC layer 200, and the crossbar 233 may be coupled to the drain of the local write transistor 222 by the BEOL metallization 211. In one embodiment, the data storage circuit 230 may include a stacked structure and the crossbar 233 may include a lower crossbar 233a coupled to the drain of the local write transistor 222, and an upper crossbar 233b coupled to the lower crossbar 233a by a connecting structure 234, wherein the plurality of capacitors 231 may be coupled to the lower crossbar 233a and the upper crossbar 233b. In one embodiment, the data storage circuit 230 may be located over the ADC circuit 210. In one embodiment, the memory structure 250 may further include a data access circuit 220 in the BEOL portion 12 of the ADC layer 200, including a BEOL read transistor 221 and a BEOL write transistor 222, wherein the data storage circuit 230 may include a lower crossbar 233a coupled to a drain of the BEOL write transistor 222 and to a gate of the BEOL read transistor 221 by BEOL metallization 211, an upper crossbar 233b coupled to the lower crossbar 233a by a connecting structure 234, and a plurality of capacitors 231 coupled to the lower crossbar 233a and the upper crossbar 233b, wherein the plurality of capacitors 231 correspond to a plurality of memory bits, respectively. In an embodiment, each of the BEOL read transistor 221 and the BEOL write transistor 222 may include a gate 621, a gate insulating layer 622 on the gate 621, a semiconductor layer 623 on the gate insulating layer 622, and a source contact 624a and drain contact 624b on opposing sides of the semiconductor layer 623. In one embodiment, the image sensor layer 100 may include a complementary metal oxide semiconductor (CMOS) image sensor layer 100. In one embodiment, the image sensor layer 100 may include a photodiode RGB array bonded to the ADC layer 200 by a direct bond. The memory structure 250 may include a 2-transistor gain cell crossbar array.

Referring again to FIGS. 1-15B, a method of making a pixel sensor 10 may include forming an image sensor layer 100, forming an analog-to-digital converter (ADC) layer 200 including an analog-to-digital converter (ADC) circuit 210, and a memory structure 250 coupled to the ADC circuit 210 including a data storage circuit 230 in a back-end-of-line (BEOL) portion 12 of the ADC layer 200, and attaching the image sensor layer 100 to the ADC layer 200. In one embodiment, the forming of the ADC layer 200 may include forming the memory structure 250 to include a data access circuit 220 in a front-end-of-line (FEOL) portion 11 of the ADC layer 200, the data access circuit 220 may include a local read transistor 221 and a local write transistor 222, and a gate of the local read transistor 221 may be coupled to a drain of the local write transistor 222. In one embodiment, the forming of the memory structure 250 may include forming the data storage circuit 230 to include a crossbar 233 coupled to the gate of the local read transistor 221 and to the drain of the local write transistor 222, and a plurality of capacitors 231 coupled to the crossbar 233.

Referring again to FIGS. 1-15B, an imaging method, may include receiving an analog signal from an image sensor layer 100, converting the analog signal to a digital signal using an analog-to-digital converter (ADC) circuit 210 in an ADC layer 200, and storing the digital signal in a memory structure 250 coupled to the ADC circuit 210, wherein the memory structure 250 may include a data storage circuit 230 in a back-end-of-line (BEOL) portion 12 of the ADC layer 200.

In one embodiment, the memory structure 250 may further include a data access circuit 220 in a front-end-of-line (FEOL) portion 11 of the ADC layer 200, and the storing of the digital signal may include accessing the memory structure 250 using a local read transistor 221 or a local write transistor 222 of the data access circuit 220. In one embodiment, the data storage circuit 230 may include a crossbar 233 coupled to the gate of the local read transistor 221 and to the drain of the local write transistor 222, and the storing of the digital signal may include storing the digital signal in a plurality of capacitors 231 coupled to the crossbar 233.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the scope of the present disclosure and the claims, and that they may make various changes, substitutions, and alterations herein without departing from the scope of the present disclosure and the claims.

What is claimed is:

1. A pixel sensor, comprising:
an image sensor layer; and
an analog-to-digital converter (ADC) layer coupled to the image sensor layer, comprising:
an analog-to-digital converter (ADC) circuit; and
a memory structure coupled to the ADC circuit, comprising a data storage circuit in a back-end-of-line (BEOL) portion of the ADC layer.

2. The pixel sensor of claim 1, wherein the memory structure further comprises a data access circuit in a front-end-of-line (FEOL) portion of the ADC layer.

3. The pixel sensor of claim 2, wherein the data access circuit comprises a local read transistor and a local write transistor, and a gate of the local read transistor is coupled to a drain of the local write transistor.

4. The pixel sensor of claim 3, wherein the data storage circuit comprises:
a crossbar coupled to the gate of the local read transistor and to the drain of the local write transistor; and
a plurality of capacitors coupled to the crossbar.

5. The pixel sensor of claim 4, wherein the plurality of capacitors comprises a plurality of ferroelectric capacitors.

6. The pixel sensor of claim 5, wherein each ferroelectric capacitor of the plurality of ferroelectric capacitors comprises:
a bottom electrode;
a ferroelectric material layer on the bottom electrode; and
a top electrode on the ferroelectric material layer.

7. The pixel sensor of claim 4, wherein the ADC layer further comprises BEOL metallization in the BEOL portion of the ADC layer, and the crossbar is coupled to the drain of the local write transistor by the BEOL metallization.

8. The pixel sensor of claim 4, wherein the data storage circuit comprises a stacked structure and the crossbar comprises:
a lower crossbar coupled to the drain of the local write transistor; and
an upper crossbar coupled to the lower crossbar by a connecting structure, wherein the plurality of capacitors is coupled to the lower crossbar and the upper crossbar.

9. The pixel sensor of claim 1, wherein the data storage circuit is located over the ADC circuit.

10. The pixel sensor of claim 1, wherein the memory structure further comprises:
a data access circuit in the BEOL portion of the ADC layer, comprising a BEOL read transistor and a BEOL write transistor, wherein the data storage circuit comprises:
a lower crossbar coupled to a drain of the BEOL write transistor and to a gate of the BEOL read transistor by BEOL metallization;
an upper crossbar coupled to the lower crossbar by a connecting structure; and
a plurality of capacitors coupled to the lower crossbar and the upper crossbar, wherein the plurality of capacitors correspond to a plurality of memory bits, respectively.

11. The pixel sensor of claim 10, wherein each of the BEOL read transistor and the BEOL write transistor comprises:
a metal gate layer;
a gate oxide layer on the metal gate layer;
a semiconducting material layer on the gate oxide layer; and
a pair of metal contacts on opposing sides of the semiconducting material layer.

12. The pixel sensor of claim 1, wherein the image sensor layer comprises a complementary metal oxide semiconductor (CMOS) image sensor layer.

13. The pixel sensor of claim 1, wherein the image sensor layer comprises a photodiode RGB array bonded to the ADC layer by a direct bond.

14. The pixel sensor of claim 1, wherein the memory structure comprises a 2-transistor gain cell crossbar array.

15. A method of making a pixel sensor, comprising:
forming an image sensor layer;
forming an analog-to-digital converter (ADC) layer comprising:
an analog-to-digital converter (ADC) circuit; and
a memory structure coupled to the ADC circuit, comprising a data storage circuit in a back-end-of-line (BEOL) portion of the ADC layer; and
attaching the image sensor layer to the ADC layer.

16. The method of claim 15, wherein the forming of the ADC layer comprises forming the memory structure to include a data access circuit in a front-end-of-line (FEOL) portion of the ADC layer, the data access circuit comprises a local read transistor and a local write transistor, and a gate of the local read transistor is coupled to a drain of the local write transistor.

17. The method of claim 16, wherein the forming of the memory structure comprises forming the data storage circuit to include a crossbar coupled to the gate of the local read transistor and to the drain of the local write transistor, and a plurality of capacitors coupled to the crossbar.

18. An imaging method, comprising:
receiving an analog signal from an image sensor layer;
converting the analog signal to a digital signal using an analog-to-digital converter (ADC) circuit in an ADC layer; and
storing the digital signal in a memory structure coupled to the ADC circuit, wherein the memory structure comprises a data storage circuit in a back-end-of-line (BEOL) portion of the ADC layer.

19. The imaging method of claim 18, wherein the memory structure further comprises a data access circuit in a front-end-of-line (FEOL) portion of the ADC layer, and the storing of the digital signal comprises accessing the memory structure using a local read transistor or a local write transistor of the data access circuit.

20. The imaging method of claim 19, wherein the data storage circuit comprises a crossbar coupled to a gate of the local read transistor and to a drain of the local write transistor, and the storing of the digital signal comprises storing the digital signal in a plurality of capacitors coupled to the crossbar.
